(19) United States
(12) Patent Application Publication
(10) Pub. No.: US 2023/0009042 A1
(43) Pub. Date: Jan. 12, 2023

(54) POWER CORD AND LEAKAGE CURRENT PROTECTION DEVICE WITH CORD CONDITION DETECTION CIRCUIT

(71) Applicant: Chengli LI, Suzhou (CN)

(72) Inventors: Chengli LI, Suzhou (CN); Shengyun NIE, Suzhou (CN)

(73) Assignee: Chengli LI, Suzhou (CN)

(21) Appl. No.: 17/388,856

(22) Filed: Jul. 29, 2021

(30) Foreign Application Priority Data
Jul. 12, 2021 (CN) 202121570209.3

(51) Int. Cl. H01B 9/02; H02H 1/00; H02H 3/16; H01B 7/02

(52) U.S. Cl. CPC H01B 9/02; H02H 1/0007; H02H 3/16; H01B 7/0216

(57) ABSTRACT

A power cord includes multiple current-carrying wires covered by an outer insulating layer, each wire including a current-carrying conductor covered by an insulating layer. At least one wire further includes a shield layer covering the insulating layer and a metal conductor between the insulating layer and the shield layer. The shield layer is formed of a band wound around the metal conductor and insulating layer. The outward-facing surface of the band is insulating; the inward-facing surface has one or more conductive regions and one or more insulating regions. One insulating region is located along a longitudinal trailing edge of the band. Consecutive turns of the band partially overlap each other; the trailing edge of a subsequent turn is disposed over part of a previous turn. The structure ensures effective insulation of the metal conductor from other components. The power cord is used in a leakage current detection and interruption device.

### BACKGROUND OF THE INVENTION

### Field of the Invention

This invention relates to electrical cords and cables, and in particular, it relates to a power cord and a leakage current protection device with a cord condition detection function.

### Description of Related Art

With the growing use of electrical appliances in homes and other places, there are increasing requirements for the safety, quality, life and cost reduction for the electrical cables and cords used with electrical appliances. To match and adapt to new requirements for various electrical appliances, requirements for the power cords used with electrical appliances are becoming higher. Conventional two-wire or multi-wire power cords include multiple current-carrying wires each separately covered with an insulating layer. For a power cord with and LCDI (leakage current detection and interruption) device, the current-carrying wires are also covered with shield layers to detect and monitor any current leakage during use.

### SUMMARY

The present invention is directed to an improved power cord, in particular, an LCDI power cord, to provide a power cord with monitoring function to detect current leakage in the power cord during use, thereby enhancing safety of the appliance.

To achieve the above objects, the present invention provides a power cord, which includes: a plurality of current-carrying wires, and an outer insulating layer covering the plurality of current-carrying wires; wherein each one of the plurality of current-carrying wires includes a current-carrying conductor and an insulating layer covering the current-carrying conductor, wherein at least a first one of the plurality of current-carrying wires further includes a shield layer covering the insulating layer and a metal conductor disposed between the insulating layer and the shield layer, and wherein the shield layer is formed of a band wound around the metal conductor and the insulating layer, the band has an inward-facing surface that faces the metal conductor and an outward-facing surface opposite to the inward-facing surface, the outward-facing surface is insulating, the inward-facing surface includes one or more conductive regions and one or more insulating regions, one of the one or more insulating regions is disposed along a longitudinal trailing edge of the inward-facing surface of the band, and wherein when wound around the metal conductor and insulating layer, consecutive turns of the band partially overlap each other, and the trailing edge of a subsequent turn is disposed over a part of a previous turn.

The power cord may have one or more of the following additional features.

In some embodiments, the shield layer includes an insulating substrate, and wherein each of the one or more conductive regions is formed of either a metal foil adhered to the insulating substrate or a metal powder coated on the insulating substrate.

In some embodiments, the one or more conductive regions include a single conductive region formed of the metal foil or metal powder and located either along another longitudinal edge of the inward-facing surface of the band or along a longitudinal center of the inward-facing surface of the band.

In some embodiments, the insulating substrate is an insulating film or insulating paper.

In some embodiments, the metal conductor includes a woven metal wire structure, or a twisted metal wire structure, or a metal wire.

In some embodiments, at least a second one of the plurality of current-carrying wires further includes a metal conductor disposed outside of the corresponding insulating layer, and wherein the metal conductor of the first current-carrying wire is insulated from the metal conductor of the second current-carrying wire.

In some embodiments, the shield layer of the first current-carrying wire is coupled in series with the metal conductor of the second current-carrying wire to form a current loop.

In some embodiments, at least a second one of the plurality of current-carrying wires further includes a shield layer covering the corresponding insulating layer and a metal conductor disposed between the insulating layer and the shield layer, wherein the metal conductor of the first current-carrying wire and the metal conductor of the second current-carrying wire are insulated from each other.

In some embodiments, the shield layer of the first current-carrying wire and the shield layer of the second current-carrying wire are coupled in series to form a current loop.

In some embodiments, the shield layer of the first current-carrying wire completely covers the metal conductor of the first current-carrying wire, and the shield layer of the second current-carrying wire completely covers the metal conductor of the second current-carrying wire.

In some embodiments, the shield layer of the first current-carrying wire is electrically coupled to the current-carrying conductor of the first or the second current-carrying wire, and the shield layer of the second current-carrying wire is electrically coupled to the current-carrying conductor of the second or the first current-carrying wire.

In another aspect, the present invention provides a leakage current detection and protection device, which includes an input end, an output end, a test assembly, and the above-described power cord, wherein when the shield layer and the metal conductor of the first current-carrying wire are electrically coupled to each other, the test assembly is user-operable for cutting off power supply from the input end to the output end, and when the shield layer and the metal conductor are electrically disconnected from each other, the test assembly is user-inoperable for cutting off power supply from the input end to the output end.

The power cord according to embodiments of the present invention can provide effective insulation between the metal conductors of the multiple current-carrying wires. By using the control circuit of the leakage current detection and protection device, device can detect whether a leakage current is present on the current-carrying wires and whether an open circuit exists along the shield layers and the metal conductors, to ensure safety. The power cord has a simple structure and low cost, and is easy to manufacture and use, making it suitable to be used in various home appliances.

### BRIEF DESCRIPTION OF THE DRAWINGS

Preferred embodiments of the present invention are described with reference to the drawings. In these drawings, like reference symbols represent like features.

FIGS. 1A and 1B are respectively a transverse cross-sectional view and a longitudinal partially-disassembled view of a conventional power cord.

FIGS. 2A and 2B are respectively a transverse cross-sectional view and a longitudinal partially-disassembled view of a power cord according to a first embodiment of the present invention.

FIGS. 3A and 3B are respectively a transverse cross-sectional view and a longitudinal partially-disassembled view of a power cord according to a second embodiment of the present invention.

FIGS. 4A and 4B are respectively a transverse cross-sectional view and a longitudinal partially-disassembled view of a power cord according to a third embodiment of the present invention.

FIGS. 5A and 5B are respectively a transverse cross-sectional view and a longitudinal partially-disassembled view of a power cord according to a fourth embodiment of the present invention.

FIGS. 6A and 6B are respectively a transverse cross-sectional view and a longitudinal partially-disassembled view of a power cord according to a fifth embodiment of the present invention.

FIG. 7 is a circuit diagram showing a leakage current detection and protection device used with the power cord according to embodiments of the present invention.

### DETAILED DESCRIPTION OF PREFERRED EMBODIMENTS

Preferred embodiments of the present and their applications are described below. It should be understood that these descriptions describe embodiments of the present invention but do not limit the scope of the invention. In this disclosure, insulating and conductive refers to electrically insulating and electrically conductive, and coupling refers to electrical or signal coupling, unless otherwise noted.

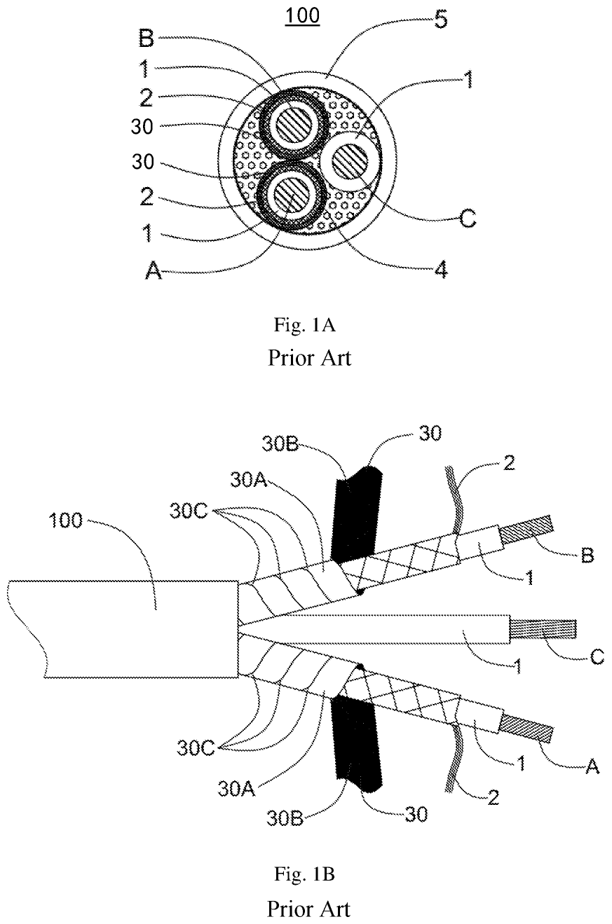

FIGS. 1A and 1B illustrate an existing three-wire LCDI power cord 100, which includes three current-carrying wires A, B, C respectively corresponding to the line (L), neutral (N) and ground (E) wires. Different from conventional power cords, in the power cord 100, each of the first current-carrying wire A, second current-carrying wire B and third current-carrying wire C includes a current-carrying conductor covered by an insulating layer 1, and further, one or two of the current-carrying wires each includes a respective shield layer 30, which functions to monitor leakage current generated by the current-carrying wires during use. A metal conductor 2 is provided between the shield layer 30 and the insulating layer 1, and functions to electrically couple to a signal or power source. A filling material 4 is optionally provided between the various current-carrying wires, and an outer insulating layer 5 forms the outer cover that covers all other layers and wires. As shown in FIG. 1B, the shield layer 30 of the existing power cord is formed of a band of single-sided insulating material wound around the metal conductor 2, the insulating layer 1 and the current-carrying conductor; the insulating side surface 30A of the band faces outwardly, and the conductive side surface 30B of the band faces inwardly toward the metal conductor 2. A problem of such a shield layer 30 is that it cannot ensure the insulating effect after the band is wound around the metal conductor 2. As shown in FIG. 1B, after winding around the conductor, in the area where two consecutive turns partially overlap each other, at the edge 30C of the subsequent turn which covers a part of the previous turn, some of the conductive material on the conductive side surface of the subsequent turn may become exposed. This may cause short circuits between the shield layer 30 and/or metal conductor 2 of different current-carrying wires.

Embodiments of the present invention improve the design of the shield layer 30 and/or metal conductor 2 of the existing power cords. By changing the structure of the shield layer, exposure of the conductive side can be avoided, and the shield layer and/or metal conductor of the various current-carrying wires can be effectively insulated from each other. In the below-described embodiments, some components and structures are similar to those of the existing cord 100, and detailed descriptions of these components and structures are omitted. In the drawings, like components are designated by like reference symbols.

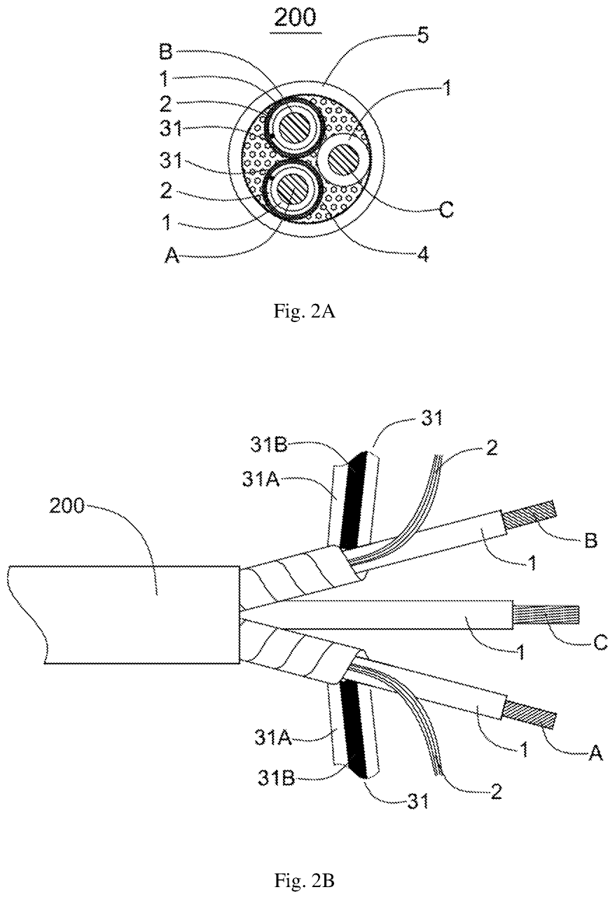

FIGS. 2A and 2B illustrate a power cord 200 according to a first embodiment of the present invention. In this power cord, in each of the two current-carrying wires A and B, an insulating layer 1 is covered by a shield layer 31, and a metal conductor 2 is provided between the insulating layer 1 and the shield layer 31. In some embodiments, the metal conductor 2 includes at least one metal conductor line, which may be disposed parallel to the current-carrying conductor or wound around the insulating layer 1. The shield layer 31 is formed of a band wound around the metal conductor 2, the insulating layer 1 and the current-carrying conductor. The band 31 has an outward-facing surface and an inward-facing surface; the outward-facing surface is completely insulating, and the inward-facing surface includes one or more conductive regions 31B and one or more insulating regions 31A. In the illustrated embodiment, a single conductive region 31B is located approximately at the longitudinal center of the inward-facing surface, with two insulating regions 31A on both sides of the conductive region extending along the two side edges of the inward-facing surface. When the shield layers 31 is wound around the metal conductor 2, the insulating layer 1 and the current-carrying conductor, the conductive region 31B physically contacts the metal conductor 2, forming an electrical and signal coupling. Meanwhile, the insulating regions 31A ensure that in the area where two consecutive turns of the wound band partially overlap each other, at the edge of the subsequent turn which covers a part of the previous turn, no parts of the conductive region 31B on the inward-facing surface will be exposed. As a result, the shield layer 31 completely covers the metal conductor 2, the insulating layer 1 and the current-carrying conductor, and ensures the insulation between the shield layers 31 of different current-carrying wires.

In this embodiment, each shield layer 31 includes a band-shaped insulating substrate. Preferably, the insulating substrate is a flexible material suitable for winding, such as an insulating film, insulating paper, etc. The insulating film may be a plastic material, such as polyester, PVC (polyvinyl chloride), etc. Preferably, the conductive regions 31B are formed by adhering a metal foil or coating a metal powder at desired locations of one surface of the insulating substrate. As examples, the metal foil may be copper, aluminum, or tin foils, etc. As examples, the metal powder may be copper, aluminum, or tin powders, etc., and may be coated on the surface of the insulating substrate by spraying or printing, etc. The remaining areas free of the metal foil or powder constitute the insulating regions 31A.

In the embodiment shown in FIG. 2B, the single conductive region 31B formed by metal foil or metal powder may be disposed at approximately the longitudinal center of the insulating substrate, and the remaining areas of the substrate on both sides of the conductive region 31B form the insulating regions 31A. Thus, after winding, in the areas where two consecutive turns partially overlap each other, insulation is well maintained. This ensures that the shield layers 31 of the current-carrying wires A and B are insulated from each other, so that the metal conductors 2 outside of insulating layers 1 of the respective current-carrying wires are insulated from each other.

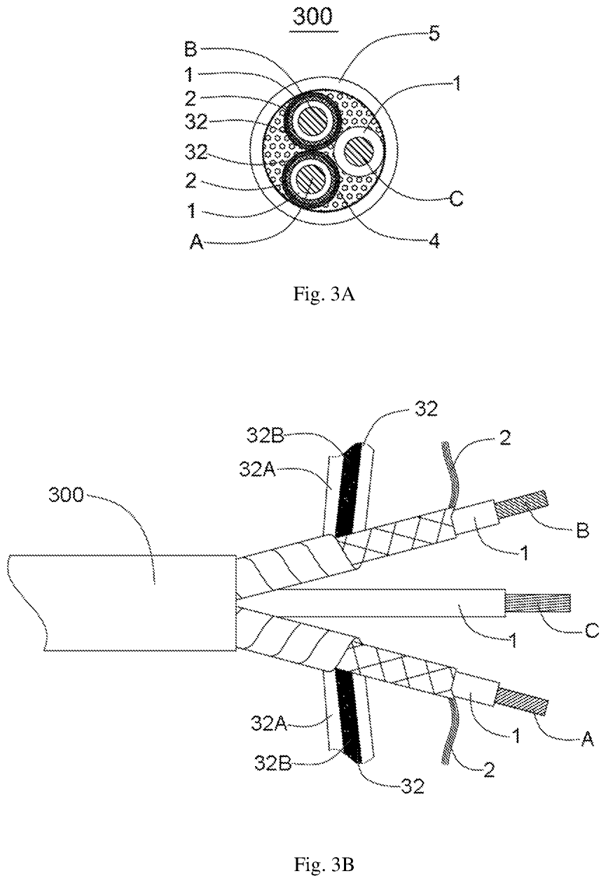

FIGS. 3A and 3B illustrate a power cord 300 according to a second embodiment of the present invention. Different from the first embodiment, each metal conductor 2 in the second embodiment is a woven metal wire structure or twisted metal wire structure. Similar to the first embodiment, for each current-carrying wire, the shield layer 32 has a conductive region 32B disposed at approximately the longitudinal center of the inward-facing surface of the band of insulating substrate, and two insulating regions 32A on the inward-facing surface are located on both sides of the conductive region 32B along the edges of the band. This ensures that the shield layers 32 of the current-carrying wires A and B are insulated from each other, so that the metal conductors 2 outside of the insulating layers 1 of the respective current-carrying wires are insulated from each other.

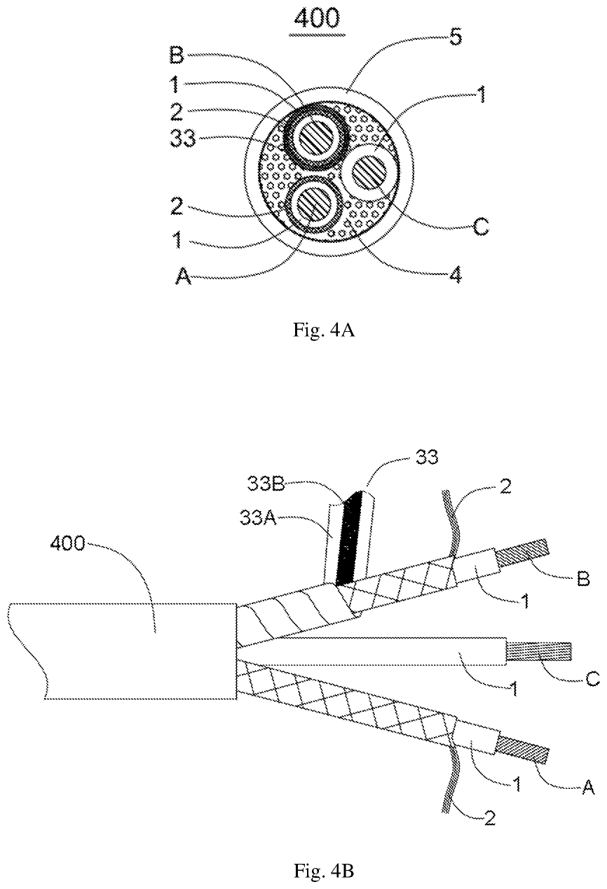

FIGS. 4A and 4B illustrate a power cord 400 according to a third embodiment of the present invention. Different from the first and second embodiments, a shield layer 33 is provided around the insulating layer 1 of only one current-carrying wire (B in this example); two metal conductors 2 are provided outside of the respective insulating layers 1 of two current-carrying wires (A and B in this example), and one of the two metal conductors 2 is covered by the shield layer 33. The shield layer 33 is similar to that of the first and second embodiment shown in FIGS. 2B and 3B, i.e., a conductive region 33B formed by metal foil or metal powder is disposed at approximately the longitudinal center of the inward-facing surface of the band of insulating substrate, and two insulating regions 33A on the inward-facing surface are located on both sides of the conductive region 33B along the edges of the band.

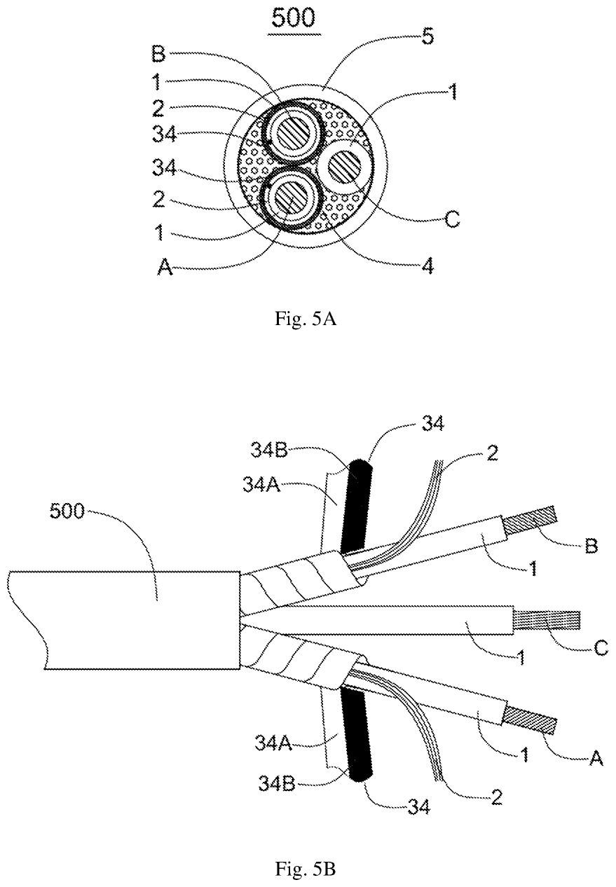

FIGS. 5A and 5B illustrate a power cord 500 according to a fourth embodiment of the present invention. Different from the first embodiment shown in FIG. 2B, for each shield layer 34, a conductive region 34B formed of metal foil or metal powder is disposed along one edge of the inward-facing surface of the band of insulating substrate; there is only one insulating region 34A on the inward-facing surface, located along another edge of the insulating substrate (the edge that will overlap a previous turn when the band is wound). After the shield layer 34 is wound around the metal conductor 2, the insulating layer 1 and the current-carrying conductor, in the areas where two consecutive turns partially overlap each other, insulation is well maintained. This ensures that the shield layers 34 of the current-carrying wires A and B are insulated from each other, so that the metal conductors 2 outside of insulating layers 1 of the respective current-carrying wires are insulated from each other.

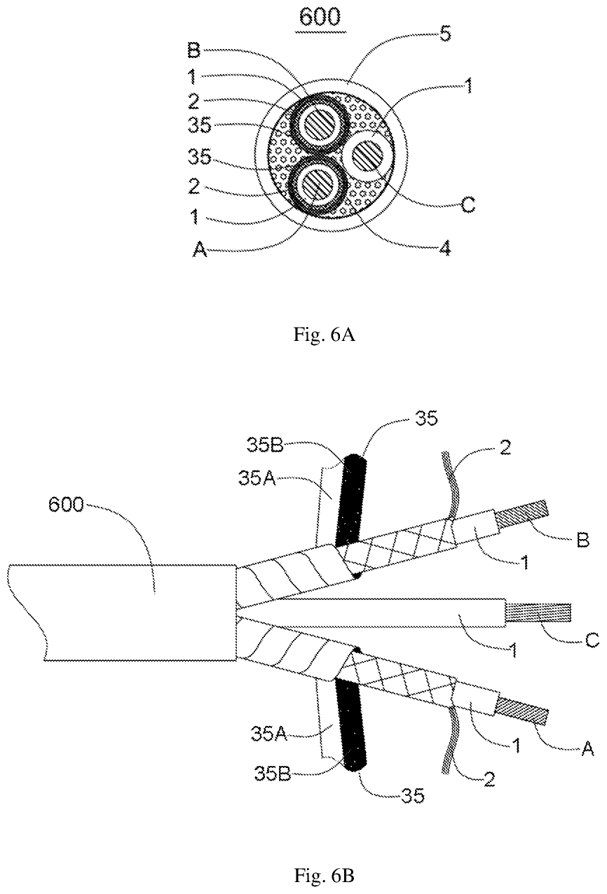

FIGS. 6A and 6B illustrate a power cord 600 according to a fifth embodiment of the present invention. Different from the second embodiment shown in FIG. 3B, for each shield layer 35, a conductive region 35B formed of metal foil or metal powder is disposed along one edge of the inward-facing surface of the band of insulating substrate; there is only one insulating region 35A on the inward-facing surface, located along another edge of the insulating substrate (the edge that will overlap a previous turn when the band is wound). After the shield layer 35 is wound around the metal conductor 2, the insulating layer 1 and the current-carrying conductor, in the areas where two consecutive turns partially overlap each other, insulation is well maintained. This ensures that the shield layers 35 of the current-carrying wires A and B are insulated from each other, so that the metal conductors 2 outside of insulating layers 1 of the respective current-carrying wires are insulated from each other.

In the embodiments shown in FIGS. 2B, 3B, 5B and 6B, where two current-carrying wires include respective shield layers, the first shield layer and the first metal conductor of the first current-carrying wire (e.g. current-carrying wire B), and the second shield layer and the second metal conductor of the second current-carrying wire (e.g. current-carrying wire A), are coupled in series with each other and form a current loop. In some embodiments, the first shield layer and the first metal conductor are coupled to the first current-carrying conductor or the second current-carrying conductor, and the second shield layer and the second metal conductor are coupled to the second current-carrying conductor or the first current-carrying conductor.

In the embodiment shown in FIGS. 4A and 4B where only one current-carrying wire includes a shield layer, the first shield layer and the first metal conductor of the first current-carrying wire (e.g. current-carrying wire B), and the second metal conductor of the second current-carrying wire (e.g. current-carrying wire A), are coupled in series with each other and form a current loop. In some embodiments, the first shield layer and the first metal conductor are coupled to the first current-carrying conductor or the second current-carrying conductor, and the second metal conductor is coupled to the second current-carrying conductor or the first current-carrying conductor.

To summarize, each shield layer 31/32/33/34/35 is formed of a band shaped material (a band) wound around the metal conductor 2 and the insulating layer 1, the band having an inward-facing surface that faces the metal conductor, and an outward-facing surface opposite to the inward-facing surface. The outward-facing surface is completely insulating, while the inward-facing surface includes one or more conductive regions and one or more insulating regions. One of the one or more insulating regions is disposed along one longitudinal edge (the trailing edge) of the inward-facing surface of the band. When wound around the metal conductor and insulating layer, consecutive turns of the band partially overlap each other, and the trailing edge of the subsequent turn is disposed over a part of the previous turn. The one insulating region disposed along the trailing edge ensure that in the area where two consecutive turns overlap each other, at the trailing edge of the subsequent turn, no parts of any conductive region on the inward-facing surface will be exposed. The locations of the other insulating regions (if any) and the one or more conductive regions are not critical. Although in FIGS. 2A-6B only one conductive region is shown, there may be multiple conductive regions, for example, all extending in the longitudinal direction of the band and arranged parallel to each other.

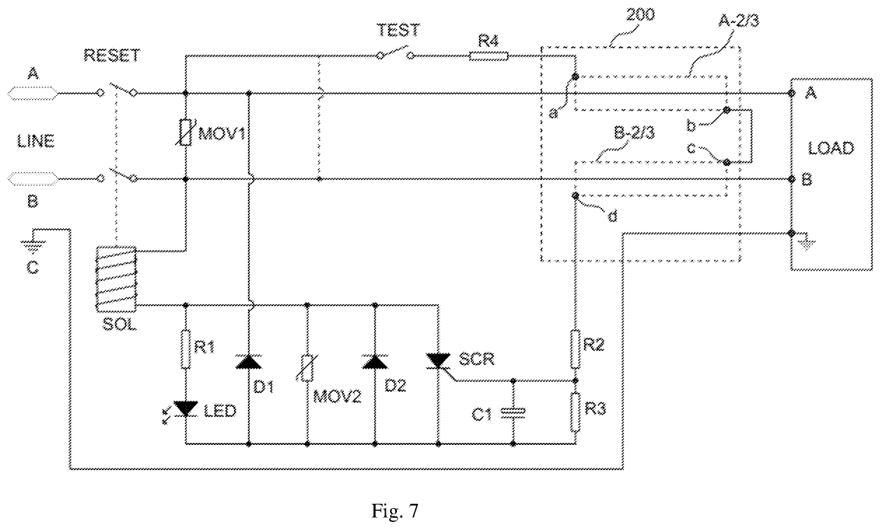

A power cord according to embodiments of the present invention may be used in an leakage current protection device (LCDI), as shown in FIG. 7. The leakage current protection device includes an input end, an output end, a test assembly, and the power cord (using power cord 200 as an example). The shield layer and metal conductor of the first current-carrying wire B of the power cord 200 (indicated as B-2/3 in FIG. 7) is coupled at one of its end d to a control circuit R2, and coupled at another of its end c to an end b of the shield layer and metal conductor of the second current-carrying wire A (indicated as A-2/3 in FIG. 7). Another end a of the shield layer and metal conductor of the second current-carrying wire A is coupled to a test resistor R4 (simulated leakage current generating element) and a test switch TEST of the test assembly.

In normal operation, the test switch TEST is normally open. When the two serial-coupled shield layers and metal conductors are coupled normally, and the test switch TEST is closed (e.g. by a user action), the voltage across resistor R3 rises, which drives the silicon-controlled rectifier SCR to become conductive. When the silicon-controlled rectifier SCR is conductive, a trip current loop is formed from the current-carrying wire B through solenoid SOL, silicon-controlled rectifier SCR, and diode D1 to the current-carrying wire A. As a result, a relatively large current flows through the solenoid SOL, generating a relatively large magnetic field to trip the reset switch RESET, thereby cutting off power supply to the load. On the other hand, if there is an open circuit anywhere along the shield layers and the metal conductors, then when the TEST switch is closed (e.g. by a user action), the voltage across resistor R3 will not rise and the silicon-controlled rectifier SCR will not become conductive; as a result, the trip current loop cannot be formed, and the power to the load cannot be cut off. This indicates to the user that the test has failed and the LCDI device should not be used any more. This way, the power cords according to embodiments of the present invention can reliably achieve LCDI functions and characteristics, and effectively achieve insulation between the shield layers and metal conductors of the current-carrying wires. Moreover, via the control circuit, the user can test whether the shield layers and metal conductors have an open circuit condition, ensuring the safety of the leakage current protection device.

It will be apparent to those skilled in the art that various modification and variations can be made in the embodiments of the present invention without departing from the spirit or scope of the invention. Thus, it is intended that the present invention cover modifications and variations that come within the scope of the appended claims and their equivalents.

1. A power cord, comprising:
a plurality of current-carrying wires; and
an outer insulating layer, covering the plurality of current-carrying wires;
wherein each one of the plurality of current-carrying wires includes a current-carrying conductor and an insulating layer covering the current-carrying conductor,
wherein at least a first one of the plurality of current-carrying wires further includes a shield layer covering the insulating layer and a metal conductor disposed between the insulating layer and the shield layer, and
wherein the shield layer is formed of a band wound around the metal conductor and the insulating layer, the band has an inward-facing surface that faces the metal conductor and an outward-facing surface opposite to the inward-facing surface, the outward-facing surface is insulating, the inward-facing surface consist of a single conductive region and a single insulating region, the insulating region is disposed along a longitudinal trailing edge relative to a direction of winding, and the conductive region is disposed along a longitudinal leading edge relative to the direction of winding, of the inward-facing surface of the band, and wherein when wound around the metal conductor and insulating layer, consecutive turns of the band partially overlap each other, and the trailing edge of a subsequent turn is disposed over a part of a previous turn.

2. The power cord of claim 1, wherein the shield layer includes an insulating substrate, and wherein more the conductive region is formed of either a metal foil adhered to the insulating substrate or a metal powder coated on the insulating substrate.

3. (canceled)

4. The power cord of claim 2, wherein the insulating substrate is an insulating film or insulating paper.

5. The power cord of claim 1, wherein the metal conductor includes a woven metal wire structure, or a twisted metal wire structure, or a metal wire.

6. The power cord of claim 1, wherein at least a second one of the plurality of current-carrying wires further includes a metal conductor disposed outside of the corresponding insulating layer, and wherein the metal conductor of the first current-carrying wire is insulated from the metal conductor of the second current-carrying wire.

7. The power cord of claim 6, wherein the shield layer of the first current-carrying wire is coupled in series with the metal conductor of the second current-carrying wire to form a current loop.

8. The power cord of claim 1, wherein at least a second one of the plurality of current-carrying wires further includes a shield layer covering the corresponding insulating layer and a metal conductor disposed between the insulating layer and the shield layer, wherein the metal conductor of the first current-carrying wire and the metal conductor of the second current-carrying wire are insulated from each other.

9. The power cord of claim 8, wherein the shield layer of the first current-carrying wire and the shield layer of the second current-carrying wire are coupled in series to form a current loop.

10. The power cord of claim 8, wherein the shield layer of the first current-carrying wire completely covers the metal conductor of the first current-carrying wire, and the shield layer of the second current-carrying wire completely covers the metal conductor of the second current-carrying wire.

11. (canceled)

12. A leakage current detection and protection device, comprising an input end, an output end, a test assembly, and the power cord of claim 1,
wherein when the shield layer and the metal conductor of the first current-carrying wire are electrically coupled to each other, the test assembly is user-operable for cutting off power supply from the input end to the output end, and when the shield layer and the metal conductor are electrically disconnected from each other, the test assembly is user-inoperable for cutting off power supply from the input end to the output end.
